(19) United States
(12) Patent Application Publication
(10) Pub. No.: US 2004/0100314 A1
(43) Pub. Date: May 27, 2004

(54) Clock squarer

(75) Inventors: Dae-Gyu Kim, Gunpo-city (KR); Jin-Ho Seo, Seoul (KR)

Correspondence Address: Anthony P. Onello, Jr., MILLS & ONELLO LLP, Suite 605, Eleven Beacon Street, Boston, MA, 02108, US

(73) Assignee: Samsung Electronics Co., Ltd.

(21) Appl. No.: 10/706,460

(22) Filed: Nov. 12, 2003

(30) Foreign Application Priority Data
Nov. 22, 2002 (KR) 02-73227

(51) Int. Cl. H03K 3/017

(52) U.S. Cl. 327/176

(57) ABSTRACT

In a clock squarer having a semiconductor chip pad and a square wave generating circuit, the clock squarer can generate a square wave having stable duty, irrespective of variation in temperature, process or supply voltage. In the clock squarer, a capacitor is provided between the chip pad and the square wave generating circuit. The clock squarer in accordance with the present invention is especially applicable to processes that involve high leakage current or a fabrication process for products requiring high-speed operation.

### RELATED APPLICATIONS

This U.S. patent application claims priority under 35 U.S.C. §119 to Korean Patent Application 2002-73227 filed on Nov. 22, 2002, the entire content of which is hereby incorporated by reference.

### BACKGROUND OF THE INVENTION

1. Field of the Invention

The present invention generally relates to a clock squarer for generating a square wave having a stable duty cycle, irrespective of variance in temperature, process or supply voltage.

2. Description of Related Art

As the integration density and the operation speed of integrated circuits rises, the problem of leakage current becomes more and more significant. Various types of leakage current are exhibited. Among them, a sub-threshold voltage leakage current and a gate leakage current caused by gate tunneling are need to be considered when designing a circuit. In particular, when I/O (Input/Output) cells of the semiconductor device employ a considerably large-sized protection element in order to protect the circuit from ESD (Electrostatic Discharge), any leakage current flowing through this element can introduce a significant problem.

As temperature, process or supply voltage vary, leakage current through pads of the I/O cells of the semiconductor device also changes accordingly. Any change in the leakage current as a result of variance in temperature is serious. For instance, a drain current (idoff) generated when an NMOS(N-type Metal-Oxide-Semiconductor) transistor or a PMOS(P-type MOS) transistor is turned off at a high temperature of 125° C. is approximately 30 times larger than that at room temperature. In addition, a leakage current generated in the pad of a circuit having MOS transistors reaches hundreds of μA. This has the same effect as connecting a resistor of a value of tens of kΩ from the pad to ground.

FIG. 1 is a circuit diagram of a conventional clock squarer, and FIG. 2 is a circuit diagram of a clock squarer of FIG. 1 when an electrostatic protection element is modeled with a resistor. As shown in FIG. 1, the clock squarer essentially comprises an inverter (INV1) and a feedback resistor (Rfb) connected between an input terminal and an output terminal of the inverter (INV1). A DC operating voltage is the same in the input terminal and the output port of the inverter (INV1). Thus, by exactly forming Vth, a voltage in the case where an input voltage is the same as an output voltage on a voltage transfer curve, of the inverter as Vdd/2, the DC operating voltage becomes Vdd/2. If there is no leakage path in the input terminal of the inverter INV1, the DC operating voltage is Vdd/2, even though the resistance of the feedback resistor Rfb is very large. As shown in FIG. 1, electrostatic protection elements MP1, MN1 are connected to the input terminal of the inverter INV1, and it is possible to model these electrostatic protection elements MP1, MN1, as shown in FIG. 2. To make the DC voltage in the input terminal equal to a DC voltage in the output terminal of the inverter INV1, a leakage current flowing through the feedback resistor Rfb should be very small to be disregarded. Since the current flowing through the electrostatic protection element reaches hundreds of μA, the feedback resistor Rfb should have a resistance value that is capable of flowing tens of mA, for example, a resistance of 1 kg, and, therefore, the size of the inverter INV1 must be large. Therefore, it is difficult to design the clock squarer having a large leakage current according to the conventional fabricating process. FIG. 3 is a diagram illustrating waveforms of main parts of the conventional clock squarer shown in FIG. 1. Referring to FIG. 3, the output voltage of the clock squarer is not in the form of a square wave under certain conditions.

### SUMMARY OF THE INVENTION

It is thus an object of the present invention to provide a clock squarer for generating a square wave having stable a duty cycle, irrespective of variance in temperature, process or supply voltage.

In a first aspect, the present invention is directed to a clock squarer having a semiconductor chip pad and a square wave generating circuit. The clock squarer includes a capacitor provided between the semiconductor chip pad and the square wave generating circuit. In response to an input signal at the chip pad, a square wave having a stable duty is generated at an output of the square wave generating circuit, irrespective of variance in environmental conditions.

The environmental conditions include, for example, at least one of temperature, process and supply voltage.

The capacitor is, for example, provided in series between the semiconductor chip pad and the square wave generating circuit. The capacitor comprises, for example, a Metal-Insulator-Metal (MIM) capacitor.

The square wave generating circuit comprises, for example, an inverter receiving an output signal of the capacitor and inverting the signal; a feedback resistor connected in parallel with the inverter; and a Schmitt trigger circuit receiving an output signal of the inverter and, in response, generating a square wave.

In another aspect, the present invention is directed to a clock squarer. The clock squarer comprises a semiconductor chip pad for connecting an external circuit with an internal circuit of a semiconductor chip; an electrostatic protective circuit connected to the semiconductor chip pad; a capacitor having a first terminal connected to the semiconductor chip pad; and a square wave generating circuit connected to a second terminal of the capacitor for generating a square wave at an output terminal thereof based on an input signal received at the semiconductor chip pad.

The electrostatic protective circuit comprises, for example, a PMOS transistor diode-connected between the semiconductor chip pad and a supply voltage; and an NMOS transistor diode-connected between the semiconductor chip pad and a ground voltage.

### BRIEF DESCRIPTION OF THE DRAWINGS

The above and other objects and advantages of the present invention will become readily apparent from the description that follows, with reference to the accompanying drawings, in which:

FIG. 1 is a circuit diagram of a conventional clock squarer.

FIG. 2 is a circuit diagram of the clock squarer of FIG. 1 in the case where the electrostatic protection elements are modeled as resistors.

FIG. 3 is a diagram illustrating input and output waveforms of the conventional clock squarer shown in FIG. 1.

FIG. 4 is a circuit diagram of a clock squarer in accordance with the present invention.

FIG. 5 is a diagram illustrating waveforms of components of the clock squarer of FIG. 4, in accordance with the present invention.

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

Hereinafter, a clock squarer in accordance with the present invention will be described in reference to the accompanying drawings.

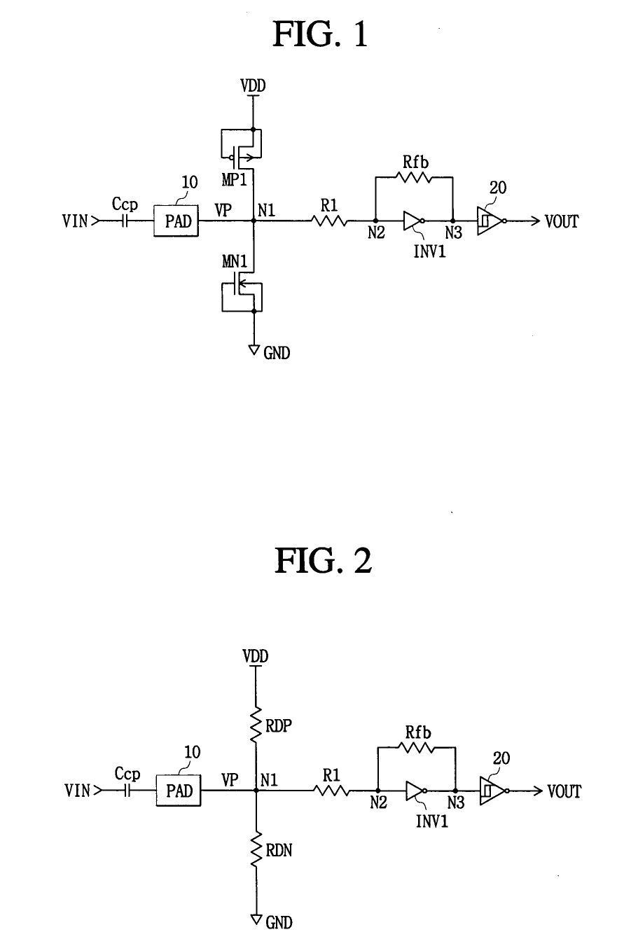

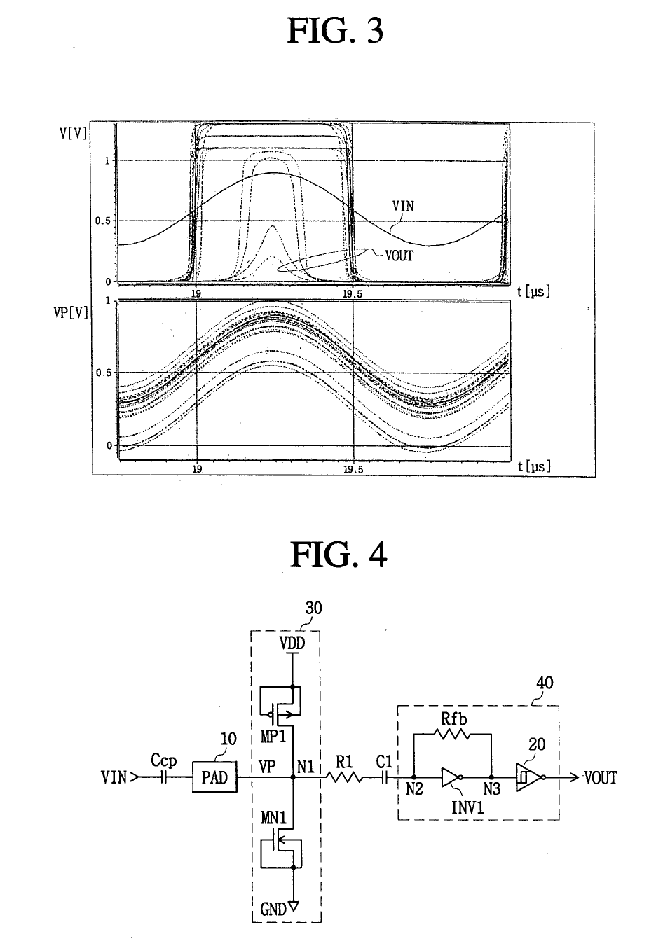

FIG. 4 is a circuit diagram of a clock squarer in accordance with the present invention. In FIG. 4, a capacitor C1 is added to the conventional clock squarer shown above in FIG. 1. The clock squarer of FIG. 4 in accordance with the present invention comprises a coupling capacitor Ccp, a pad 10, an electrostatic protective circuit 30, a resistor R1, a capacitor C1, and a square wave generating circuit 40. The electrostatic protective circuit (30) includes a PMOS transistor MP1 and an NMOS transistor MN1, each of them being configured as a diode connection. The square wave generating circuit (40) includes an inverter INV1, a feedback resistor Rfb connected to the inverter INV1 in parallel, and a Schmitt trigger circuit 20 connected to an output terminal of the inverter INV1.

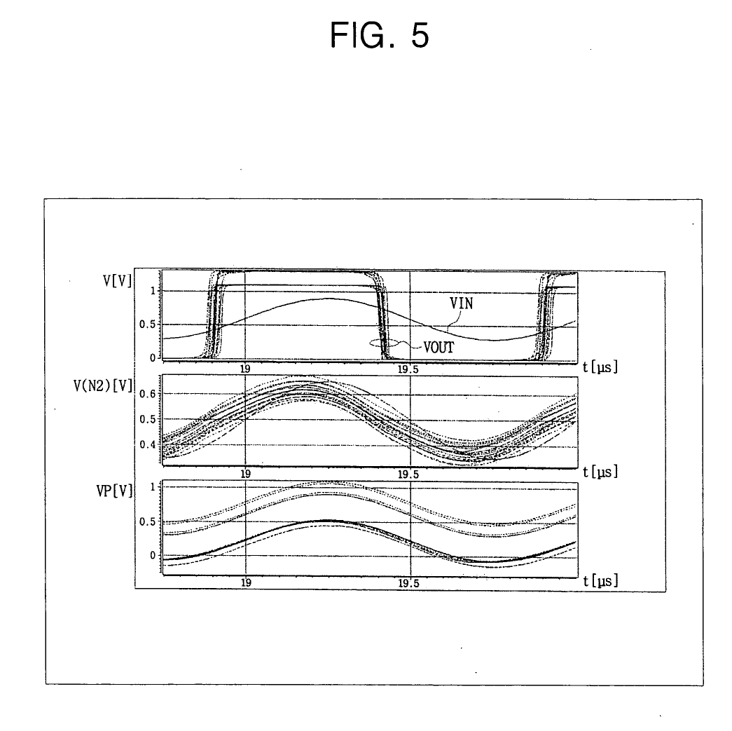

FIG. 5 is a diagram illustrating waveforms of the clock squarer of FIG. 4, in accordance with the present invention.

Hereinafter, the operation of the clock squarer in accordance with the present invention will be described in reference to FIG. 4 and FIG. 5.

The coupling capacitor Ccp, receives input voltage VIN signal, removes the DC component, and passes only the AC component of the signal. The pad 10 receives the output of the coupling capacitor Ccp, and transmits the output to a semiconductor chip that includes the pad 10. The electrostatic protective circuit 30 comprises a PMOS transistor MP1 connected between a supply voltage VDD and a first node N1 and an NMOS transistor MN1 connected between the first node N1 and a ground GND. When static electricity is generated in the pad 10, the electrostatic protective circuit 30 protects the internal circuits of the semiconductor chip by forming a current path. From node N1 of the ESD protective circuit, the signal passes through resistor R1 and capacitor C1, to the square wave generating circuit 40. The square wave generating circuit 40 receives the voltage signal received from the capacitor C1, and converts it to a square wave. The inverter INV1 receives the signal passing through the capacitor C1, inverts the signal, and amplifies the signal. The Schmidtt trigger circuit 20 receives an output signal of the inverter INV1, and generates a square wave that is provided at output terminal VOUT.

The pad 10 is isolated from the input terminal of the square wave generating circuit 40 in DC by inserting the series capacitor C1. Thus, a voltage change in the pad as a result of variance in temperature, process or supply voltage changes does not influence the input terminal of the square wave generating circuit 40. The DC operating voltage of the inverter INV1 is determined by the amount of current flowing through the feedback resistor Rfb and the leakage current generated at the node N1. Assuming that it is possible to disregard the leakage current caused by the capacitor C1 and the gate leakage current of the inverter INV1, the DC operating voltage of the inverter INV1 is primarily determined by the feedback resistor Rfb. Even in the case where a process is used that results in high leakage current, if the size of the inverter INV1 is not large and a Metal-Insulator-Metal (MIM) capacitor with high accuracy is used as the capacitor C1, it is possible to make the leakage current much smaller than the current flowing through the feedback resistor Rfb. Accordingly, the operating voltage V of the input terminal at node N2 of the square wave generating circuit 40 can have a stable value of around VDD/2. In the meantime, since the leakage current generated at node N2 can be sufficiently reduced, it is possible to design the resistance of the feedback resistor Rfb to have a relatively small size. When determining the resistance value of the feedback resistor Rfb, it is essential to consider the leakage current generated at the node N2, the capacitor C1 value, and the frequency of the input signal VIN input to the pad 10.

In the conventional approach, leakage current flowing through the electrostatic protection elements MP1, MN1 is changed in response to variations in temperature, process or supply voltage. Accordingly, the pad voltage VP is changed and the resulting output voltage VOUT may not be a square wave under certain conditions.

The clock squarer in accordance with the present invention shown in FIG. 4 includes the series capacitor C1 at the input terminal N2 of the square wave generating circuit 40. Therefore, the input terminal voltage at node N2 of the square wave generating circuit 40 can maintain a stable voltage of approximately the VDD/2 and thus the output voltage of the clock squarer is a substantially perfect square wave, even though the pad voltage VP may change in response to variance in temperature, process or supply voltage.

While this invention has been particularly shown and described with references to preferred embodiments thereof, it will be understood by those skilled in the art that various changes in form and details may be made herein without departing from the spirit and scope of the invention as defined by the appended claims.

As described above, the clock squarer in accordance with the present invention can generate a square wave having stable duty cycles, irrespective of variation in temperature, process or supply voltage.

What is claimed is:

1. A clock squarer having a semiconductor chip pad and a square wave generating circuit, the clock squarer including a capacitor provided between the semiconductor chip pad and the square wave generating circuit, wherein, in response to an input signal at the chip pad, a square wave having a stable duty is generated at an output of the square wave generating circuit, irrespective of variance in environmental conditions.

2. The clock squarer of claim 1 wherein the environmental conditions include at least one of temperature, process and supply voltage.

3. The clock squarer of claim 1 wherein the capacitor is provided in series between the semiconductor chip pad and the square wave generating circuit.

4. The clock squarer of claim 1, wherein the square wave generating circuit comprises:
an inverter receiving an output signal of the capacitor and inverting the signal;
a feedback resistor connected in parallel with the inverter; and
a Schmitt trigger circuit receiving an output signal of the inverter and, in response, generating a square wave.

5. The clock squarer of claim 1, wherein the capacitor comprises a Metal-Insulator-Metal (MIM) capacitor.

6. A clock squarer, comprising:
a semiconductor chip pad for connecting an external circuit with an internal circuit of a semiconductor chip;
an electrostatic protective circuit connected to the semiconductor chip pad;
a capacitor having a first terminal connected to the semiconductor chip pad; and
a square wave generating circuit connected to a second terminal of the capacitor for generating a square wave at an output terminal thereof based on an input signal received at the semiconductor chip pad.

7. The clock squarer of claim 6, wherein the electrostatic protective circuit comprises:
a PMOS transistor diode-connected between the semiconductor chip pad and a supply voltage; and
an NMOS transistor diode-connected between the semiconductor chip pad and a ground voltage.

8. The clock squarer of claim 6, wherein the square wave generating circuit comprises:
an inverter receiving an output signal of the capacitor and inverting the signal;
a feedback resistor connected in parallel with the inverter; and
a Schmitt trigger circuit receiving an output signal of the inverter and, in response, generating a square wave.

9. The clock square of claim 6, wherein the capacitor is comprises a Metal-Insulator-Metal (MIM) capacitor.

10. The clock squarer of claim 6 wherein the capacitor is connected in series between the semiconductor chip pad and the square wave generating circuit.
